(19) United States
(12) Patent Application Publication
(10) Pub. No.: US 2016/0143134 A1
(43) Pub. Date: May 19, 2016

(54) WIRING BOARD WITH BUILT-IN METAL BLOCK AND METHOD FOR MANUFACTURING THE SAME

(71) Applicant: IBIDEN CO., LTD., Ogaki (JP)

(72) Inventors: Mitsuhiro TOMIKAWA, Ogaki (JP); Koji ASANO, Ogaki (JP); Kotaro TAKAGI, Ogaki (JP)

(73) Assignee: IBIDEN CO., LTD., Ogaki (JP)

(21) Appl. No.: 14/943,340

(22) Filed: Nov. 17, 2015

(30) Foreign Application Priority Data
Nov. 17, 2014 (JP) 2014-232628

(51) Int. Cl. H05K 1/03; H05K 3/00; H05K 3/40; H05K 1/11

(52) U.S. Cl. CPC H05K 1/0313; H05K 1/115; H05K 3/0058; H05K 3/4038; H05K 3/0017; H05K 2201/09209; H05K 2201/10015

(57) ABSTRACT

A wiring board with built-in metal block includes a substrate having a cavity penetrating through the substrate, a metal block accommodated in the cavity and having first surface, second surface, and side surface connecting outer edges of the first and second surface, filling resin filling gap between inner side surface of the substrate in the cavity and the side surface of the block, a first build-up layer laminated on first surface of the substrate and including an insulating layer such that the first layer is covering the cavity and the first surface of the block, and a second build-up layer laminated on second surface of the substrate and including an insulating layer such that the second layer is covering the cavity and the second surface of the block. The side surface of the block is recessed such that the side surface of the block is forming a groove shape.

### CROSS-REFERENCE TO RELATED APPLICATIONS

The present application is based upon and claims the benefit of priority to Japanese Patent Application No. 2014-232628, filed Nov. 17, 2014, the entire contents of which are incorporated herein by reference.

### BACKGROUND OF THE INVENTION

1. Field of the Invention

The present invention relates to a wiring board with a built-in metal block, in which a metal block is accommodated in a cavity that is formed in a substrate, and relates to a method for manufacturing the wiring board with a built-in metal block.

2. Description of Background Art

Japanese Patent Laid-Open Publication No. 2013-135168 describes a wiring board with a built-in metal block, in which a metal block is fixed in a substrate by a filling resin. The entire contents of this publication are incorporated herein by reference.

### SUMMARY OF THE INVENTION

According to one aspect of the present invention, a wiring board with a built-in metal block includes a substrate having a cavity such that the cavity is penetrating through the substrate, a metal block accommodated in the cavity of the substrate and formed such that the metal block has a first surface, a second surface on an opposite side of the first surface, and a side surface connecting an outer edge of the first surface and an outer edge of the second surface, a filling resin filling a gap formed between an inner side surface of the substrate in the cavity and the side surface of the metal block, a first build-up layer laminated on a first surface of the substrate and including an insulating resin layer such that the first build-up layer is covering the cavity and the first surface of the metal block in the cavity, and a second build-up layer laminated on a second surface of the substrate and including an insulating resin layer such that the second build-up layer is covering the cavity and the second surface of the metal block in the cavity. The side surface of the metal block is recessed such that the side surface of the metal block is forming a groove shape.

According to another aspect of the present invention, a method for manufacturing a wiring board with a built-in metal block includes forming a cavity in a substrate such that the cavity penetrates through the substrate, accommodating a metal block in the cavity of the substrate such that the metal block has a first surface on a first surface side of the substrate, a second surface on a second surface side of the substrate on an opposite side of the first surface, and a side surface connecting an outer edge of the first surface and an outer edge of the second surface, filling a filling resin into a gap formed between an inner side surface of the substrate in the cavity and the side surface of the metal block, forming a first build-up layer laminated on the first surface side of the substrate and including an insulating resin layer such that the first build-up layer covers the cavity and the first surface of the metal block in the cavity, and forming a second build-up layer laminated on a second side of the substrate and including an insulating resin layer such that the second build-up layer covers the cavity and the second surface of the metal block in the cavity. The side surface of the metal block is recessed such that the side surface of the metal block is forming a groove shape.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a plan view of a wiring board with a built-in metal block according to a first embodiment of the present invention;

FIG. 2 is a plan view of a product region in the wiring board with a built-in metal block;

FIG. 3 is a cross-sectional side view of the wiring board with a built-in metal block in an A-A cutting plane of FIG. 2;

FIG. 4A-4D are cross-sectional side views illustrating processes for manufacturing the wiring board with a built-in metal block;

FIG. 5A-5D are cross-sectional side views illustrating processes for manufacturing the wiring board with a built-in metal block;

FIG. 6A-6D are cross-sectional side views illustrating processes for manufacturing the wiring board with a built-in metal block;

FIG. 7A-7C are cross-sectional side views illustrating processes for manufacturing the wiring board with a built-in metal block;

FIG. 8A-8C are cross-sectional side views illustrating processes for manufacturing the wiring board with a built-in metal block;

FIG. 9 is a cross-sectional side view illustrating a process for manufacturing the wiring board with a built-in metal block;

FIG. 10A-10E are cross-sectional side views illustrating processes for manufacturing a metal block;

FIG. 11 is a cross-sectional side view of a PoP that includes the wiring board with a built-in metal block;

FIG. 12 is a cross-sectional side view of a wiring board with a built-in metal block according to a second embodiment;

FIG. 13 is a cross-sectional side view of a wiring board with a built-in metal block according to a third embodiment;

FIG. 14 is a cross-sectional side view of a wiring board with a built-in metal block according to a modified embodiment; and

FIG. 15 is a plan view of the wiring board with a built-in metal block according to the modified embodiment.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

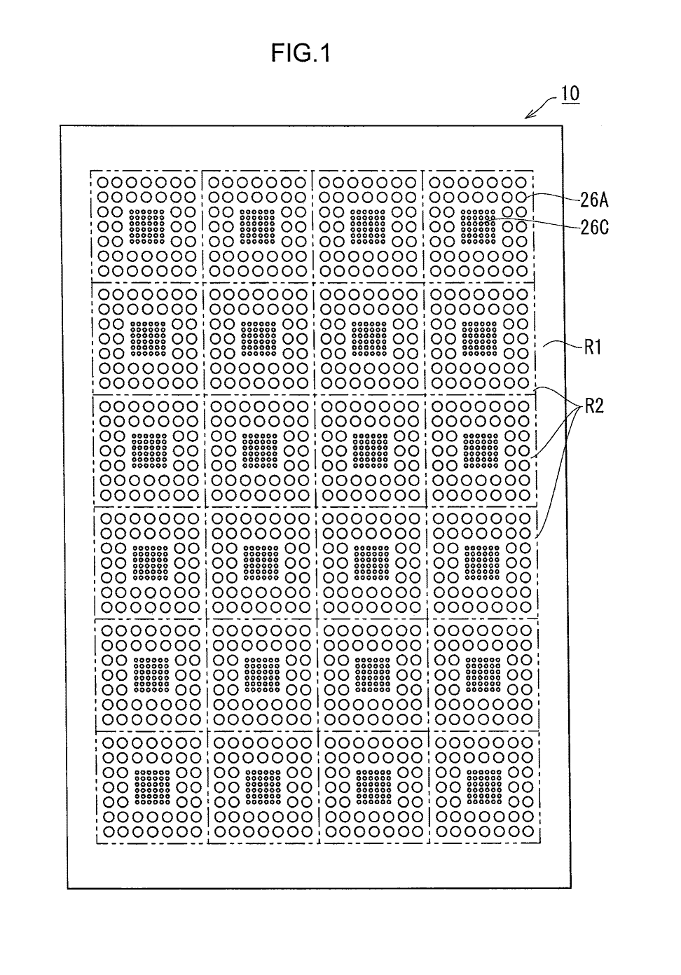

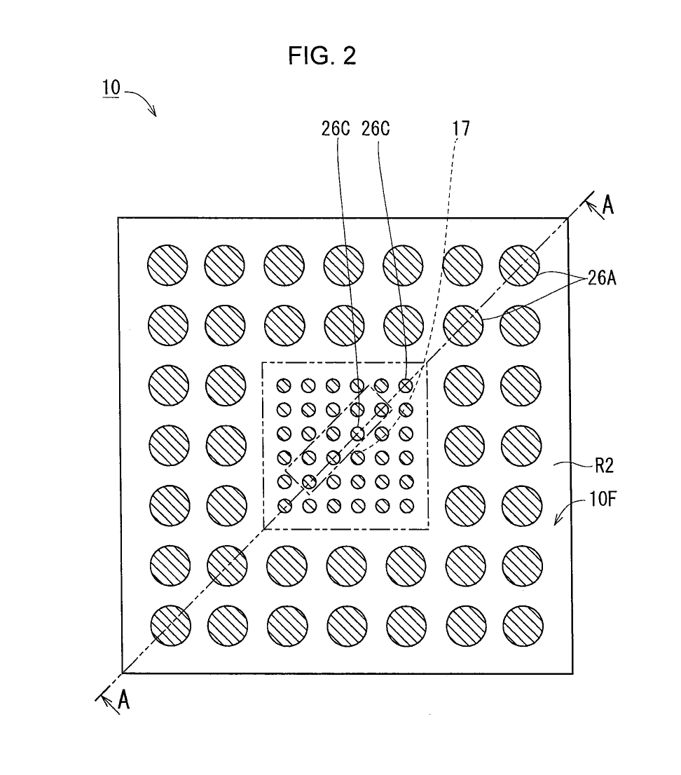

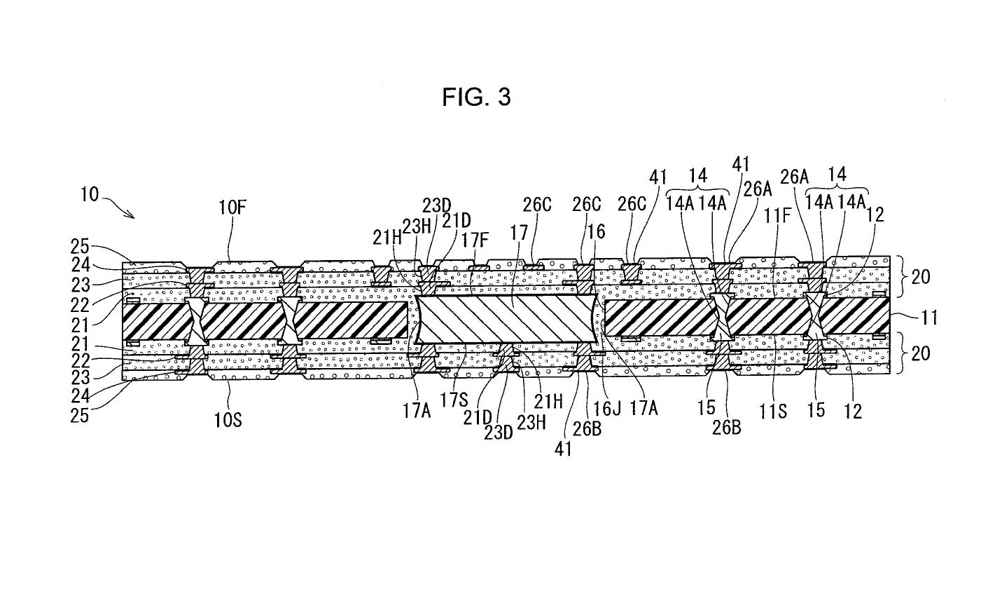

In the following, a first embodiment of the present invention is described based on FIG. 1-11. As illustrated in a plan view of FIG. 1, a wiring board 10 with a built-in metal block of the present embodiment has, for example, a frame-shaped discard region (R1) along an outer edge, and an inner side of the discard region (R1) is divided into multiple square product regions (R2). FIG. 2 illustrates an enlarged view of one product region (R2). FIG. 3 illustrates an enlarged view of a cross-sectional structure of the wiring board 10 with a built-in metal block, the cross section being taken by cutting the product region (R2) along a diagonal line.

As illustrated in FIG. 3, the wiring board 10 with a built-in metal block is structured to respectively have build-up layers (20, 20) on front and back surfaces of a core substrate 11. The core substrate 11 is formed of an insulating member. A conductor circuit layer 12 is formed on each of an F surface (11F), which is the front side surface of the core substrate 11, and an S surface (11S), which is the back side surface of the core substrate 11. Further, a cavity 16 and multiple electrical conduction through holes 14 are formed in the core substrate 11.

The electrical conduction through holes 14 are each formed in a middle-constricted shape in which small diameter side ends of tapered holes (14A, 14A) are communicatively connected, the tapered holes (14A, 14A) being respective formed by drilling from the F surface (11F) and the S surface (11S) of the core substrate 11 and being gradually reduced in diameter toward a deep side. On the other hand, the cavity 16 is formed in a shape that has a space in a shape of a rectangular cuboid.

The electrical conduction through holes 14 are filled with plating and multiple through-hole electrical conductors 15 are respectively formed. The conductor circuit layer 12 on the F surface (11F) and the conductor circuit layer 12 on the S surface (11S) are connected by the through-hole electrical conductors 15.

A metal block 17 is accommodated in the cavity 16. The metal block 17 is, for example, a copper cuboid. A planar shape of the metal block 17 is slightly smaller than a planar shape of the cavity 16. Further, a thickness of the metal block 17, that is, a distance between a first primary surface (17F) (which is one of front and back surfaces of the metal block 17) and a second primary surface (17S) (which is the other one of the front and back surfaces of the metal block 17), is slightly larger than a plate thickness of the core substrate 11. Then, the metal block 17 slightly protrudes from both the F surface (11F) and the S surface (11S) of the core substrate 11. The first primary surface (17F) of the metal block 17 is substantially flush with an outermost surface of the conductor circuit layer 12 on the F surface (11F) of the core substrate 11, and the second primary surface (17S) of the metal block 17 is substantially flush with an outermost surface of the conductor circuit layer 12 on the S surface (11S) of the core substrate 11. Further, a gap between the metal block 17 and an inner surface of the cavity 16 is filled with a filling resin (16J) according to the present invention. Here, thermal expansion coefficients of the metal block 17, the filling resin (16J) and the core substrate 11 are respectively, for example, 17 ppm/° C., 23 ppm/° C. and 10 ppm/° C. (thermal expansion coefficient of the core substrate 11 in a direction parallel to the front and back surfaces of the core substrate 11). A difference between the thermal expansion coefficient of the metal block 17 and the thermal expansion coefficient of the filling resin (16J) is smaller than a difference between the thermal expansion coefficient of the metal block 17 and the thermal expansion coefficient of the core substrate 11 in a direction parallel to the front and back surfaces of the core substrate 11.

The first primary surface (17F) and the second primary surface (17S) of the metal block 17 have substantially the same area and are parallel to each other. Further, four side surfaces of the metal block 17 between an outer edge of the first primary surface (17F) and an outer edge of the second primary surface (17S) are groove-shaped side surfaces (17A) (corresponding to “side surfaces” of the present invention) that are each curved so as to increase in depth toward a center between the first primary surface (17F) and the second primary surface (17S). Each corner formed the groove-shaped side surface (17A) and the first primary surface (17F) or the second primary surface (17S) has an acute angle of 30 degrees or more and less than 90 degrees. Further, a maximum depth of each of the groove-shaped side surfaces (17A) is 10-20% of the thickness of the metal block 17 (a distance between the first primary surface (17F) and the second primary surface (17S) and is, for example, 10-20 μm.

Further, the first primary surface (17F), the second primary surface (17S) and the groove-shaped side surfaces (17A) of the metal block 17 (that is, all of the outer surfaces of the metal block 17) are rough surfaces. Specifically, the metal block 17 is immersed in an acid solution (for example, an acid of which main components are sulfuric acid and hydrogen peroxide) for a predetermined time period to erode the surfaces and thereby the surfaces of the metal block 17 have an arithmetic average roughness (Ra) of 0.1 μm-3.0 μm (according to a definition of JIS B 0601-1994).

Both the build-up layer 20 on the F surface (11F) side of the core substrate 11 and the build-up layer 20 on the S surface (11S) side are formed by sequentially laminating, from the core substrate 11 side, a first insulating resin layer 21, a first conductor layer 22, a second insulating resin layer 23 and a second conductor layer 24. A solder resist layer 25 is laminated on the second conductor layer 24. Further, multiple via holes (21H) and multiple via holes (23H) are respectively formed in the first insulating resin layer 21 and the second insulating resin layer 23. The via holes (21H, 23H) are all formed in a tapered shape that is gradually reduced in diameter toward the core substrate 11 side. Further, the via holes (21H, 23H) are filled with plating and multiple via conductors (21D, 23D) are formed. Then, the conductor circuit layer 12 and the first conductor layer 22, and, the metal block 17 and the first conductor layer 22, are connected by the via conductors (21D) of the first insulating resin layer 21; and the first conductor layer 22 and the second conductor layer 24 are connected by the via conductors (23D) of the second insulating resin layer 23. Further, multiple pad holes are formed in the solder resist layer 25, and a portion of the second conductor layer 24 positioned in each of the pad holes becomes a pad 26.

On an F surface (10F) of the wiring board 10 with a built-in metal block (the F surface (10F) being an outermost surface of the build-up layer 20 on the F surface (11F) of the core substrate 11), the pads 26 include a group of large pads (26A) that are arranged in two rows along an outer edge of the product region (R2) and a group of small pads (26C) that are arranged in vertical and horizontal rows in an inner side region surrounded by the group of the large pads (26A). Further, for example, as illustrated in FIG. 2, the metal block 17 is arranged at a position directly below a total of seven small pads (26C) including four small pads (26C) that are aligned on a diagonal line of the product region (R2) at a center of the group of the small pads (26C) and three small pads (26C) that are aligned parallel to the diagonal line next to the array of the four small pads (26C). Then, among the seven small pads (26C), as illustrated in FIG. 3, for example, two small pads (26C) are connected to the metal block 17 via four via conductors (21D, 23D). In contrast, on an S surface (10S) of the wiring board 10 with a built-in metal block (the S surface (10S) being an outermost surface of the build-up layer 20 on the S surface (11S) of the core substrate 11), three medium pads (26B) that are larger than the small pads (26C) are connected to the metal block 17 via six via conductors (21D, 23D). That is, in the wiring board 10 with a built-in metal block of the present embodiment, the number of the via conductors (21D) that are connected to the metal block 17 is greater in the build-up layer 20 on the S surface (11S) side of the core substrate 11 than in the build-up layer 20 on the F surface (11F) side.

The wiring board 10 with a built-in metal block of the present embodiment is manufactured as follows.

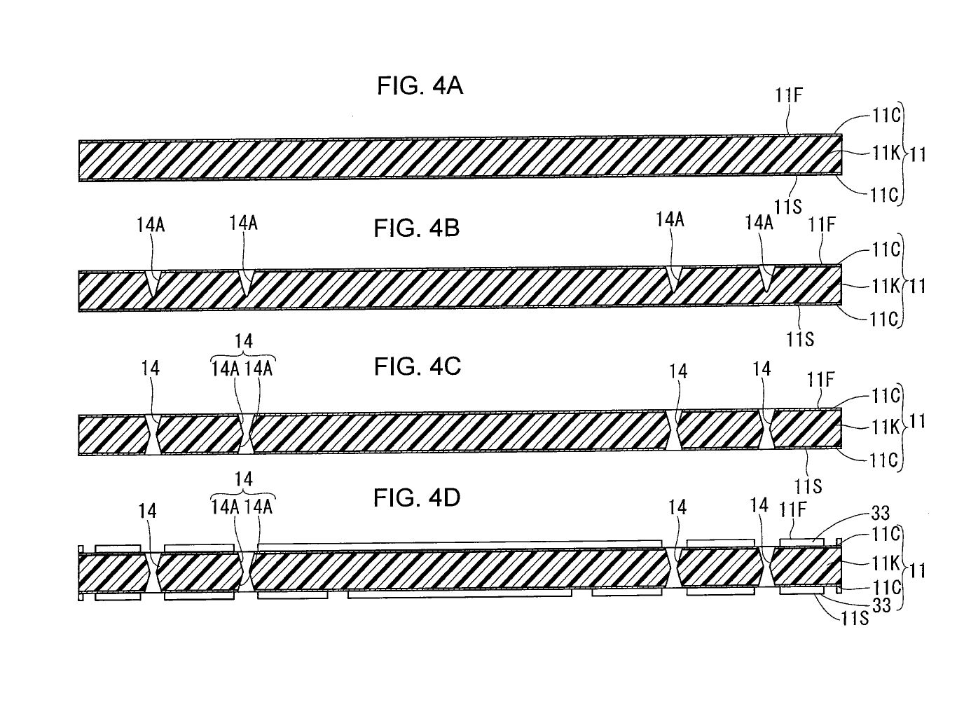

(1) As illustrated in FIG. 4A, a substrate as the core substrate 11 is prepared that is obtained by laminating a copper foil (11C) on each of both front and back surfaces of an insulating base material (11K) that is made of an epoxy resin or a BT (bismaleimide triazine) resin and a reinforcing material such as a glass cloth.

(2) As illustrated in FIG. 4B, the tapered holes (14A) for forming the electrical conduction through holes 14 (see FIG. 3) are drilled by irradiating, for example, CO2 laser to the core substrate 11 from the F surface (11F) side.

(3) As illustrated in FIG. 4C, the tapered holes (14A) are drilled on the S surface (11S) side of the core substrate 11 by irradiating CO2 laser to positions directly on the back of the above-described tapered holes (14A) on the F surface (11F) side. The electrical conduction through holes 14 are formed from the tapered holes (14A, 14A).

(4) An electroless plating treatment is performed. An electroless plating film (not illustrated in the drawings) is formed on the copper foil (11C) and on inner surfaces of the electrical conduction through holes 14.

(5) As illustrated in FIG. 4D, a plating resist 33 of a predetermined pattern is formed on the electroless plating film on the copper foil (11C).

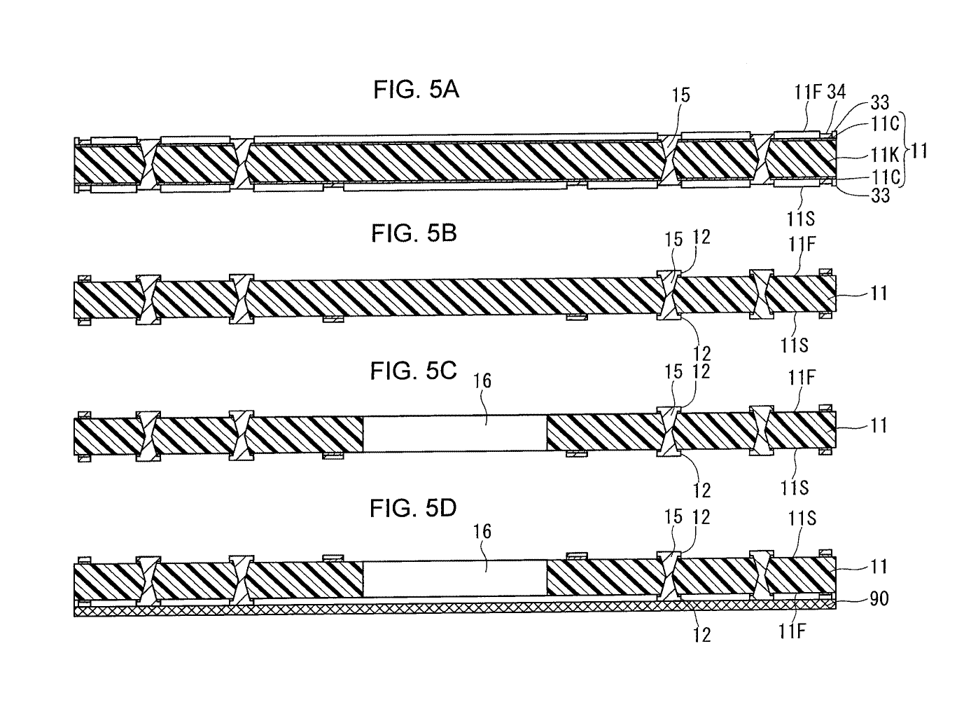

(6) An electrolytic plating treatment is performed. As illustrated in FIG. 5A, the electrical conduction through holes 14 are filled with electrolytic plating and the through-hole electrical conductors 15 are formed; and an electrolytic plating film 34 is formed on a portion of the electroless plating film (not illustrated in the drawings) on the copper foil (11C), the portion being exposed from the plating resist 33.

(7) The plating resist 33 is peeled off, and the electroless plating film (not illustrated in the drawings) and the copper foil (11C), which are below the plating resist 33, are removed. As illustrated in FIG. 5B, by the remaining electrolytic plating film 34, electroless plating film and copper foil (11C), the conductor circuit layer 12 is formed on the F surface (11F) of the core substrate 11, and the conductor circuit layer 12 is formed on the S surface (11S) of the core substrate 11. Then, the conductor circuit layer 12 on the F surface (11F) and the conductor circuit layer 12 on the S surface (11S) are in a state of being connected by the through-hole electrical conductors 15.

(8) As illustrated in FIG. 5C, the cavity 16 is formed in the core substrate 11 using a router or CO2 laser.

(9) As illustrated in FIG. 5D, a tape 90 made of a PET film is affixed to the F surface (11F) of the core substrate 11 so as to close the cavity 16.

(10) The metal block 17 is prepared that is manufactured using a method to be described later.

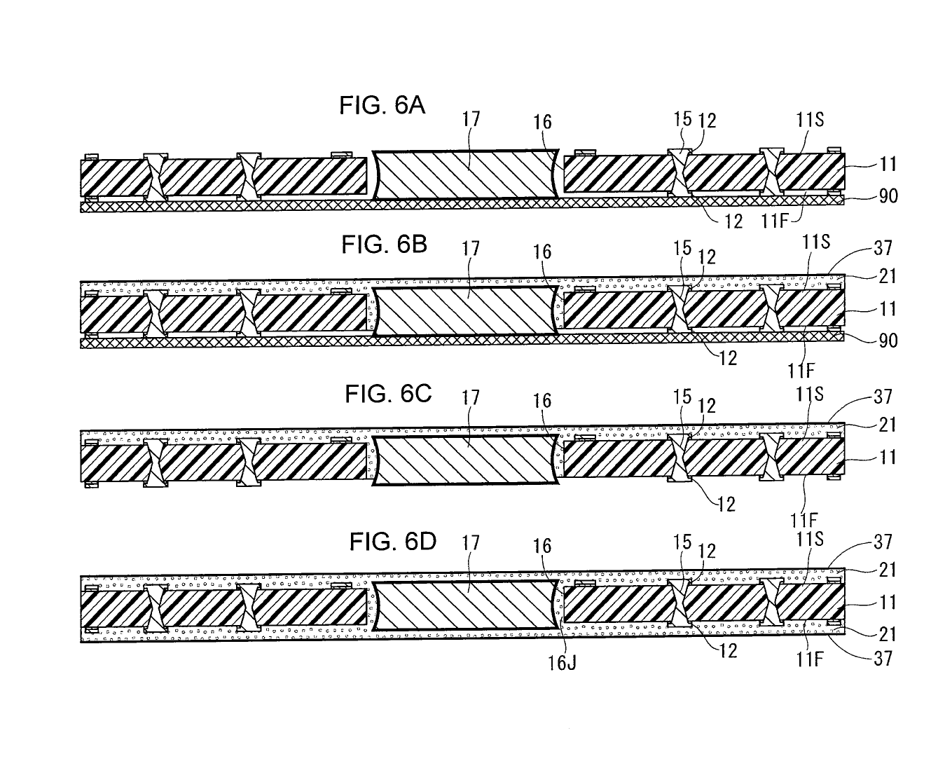

(11) As illustrated in FIG. 6A, the metal block 17 is accommodated in the cavity 16 using a mounter (not illustrated in the drawings).

(12) As illustrated in FIG. 6B, a prepreg (a resin sheet of a B-stage formed by impregnating a core material with a resin) as the first insulating resin layer 21 and a copper foil 37 are laminated on the conductor circuit layer 12 on the S surface (11S) of the core substrate 11, and then, the resulting substrate is hot-pressed. In doing so, spacing between the conductor circuit layers (12, 12) on the S surface (11S) of the core substrate 11 is filled with the prepreg, and a gap between the inner surface of the cavity 16 and the metal block 17 is filled with a thermosetting resin exuded from the prepreg.

(13) As illustrated in FIG. 6C, the tape 90 is removed.

(14) As illustrated in FIG. 6D, a prepreg as the first insulating resin layer 21 and a copper foil 37 are laminated on the conductor circuit layer 12 on the F surface (11F) of the core substrate 11, and then, the resulting substrate is hot-pressed. In doing so, spacing between the conductor circuit layers (12, 12) on the F surface (11F) of the core substrate 11 is filled with the prepreg, and a gap between an inner surface of the cavity 16 and the metal block 17 is filled with a thermosetting resin exuded from the prepreg. Further, the above-described filling resin (16J) is formed by the thermosetting resin that exudes from the prepregs on the F surface (11F) and the S surface (11S) of the core substrate 11 and is filled in the gap between the inner surface of the cavity 16 and the metal block 17.

Instead of the prepreg, it is also possible to use a resin film that does not contain a core material as the first insulating resin layer 21. In this case, without laminating a copper foil, a conductor circuit layer can be directly formed on a surface of the resin film using a semi-additive method.

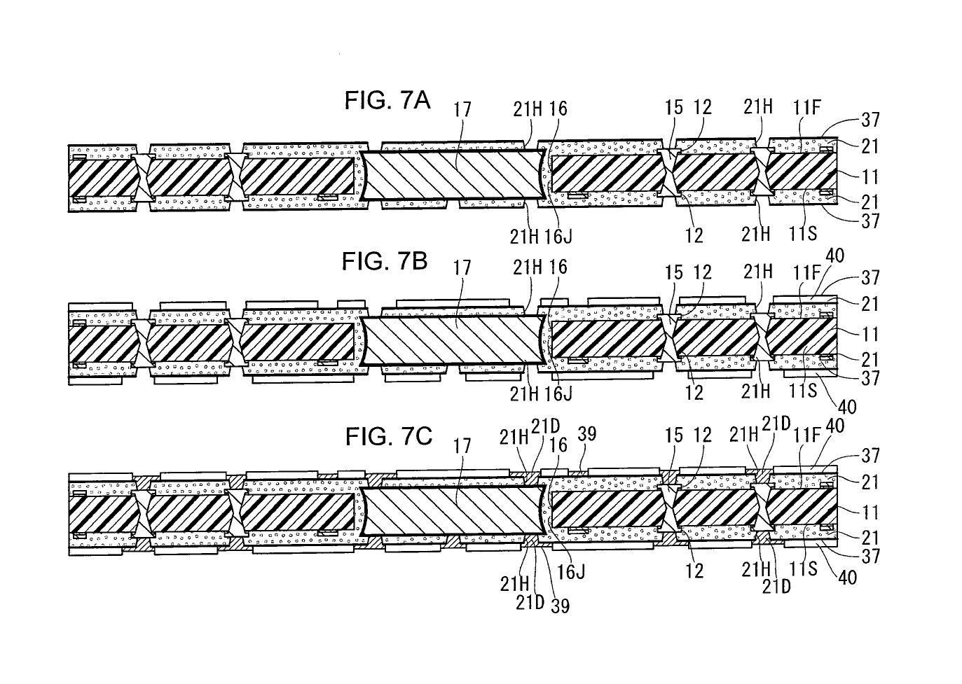

(15) As illustrated in FIG. 7A, the via holes (21H) are formed by irradiating CO2 laser to the first insulating resin layers (21, 21) that are respectively formed on the front and back sides of the core substrate 11 by the prepregs. Among the via holes (21H), some via holes (21H) are arranged on the conductor circuit layers 12 and other via holes (21H) are arranged on the metal block 17. When the via holes (21H) are formed on the metal block 17, unevenness of the rough surface of the metal block 17 positioned on a deep side of the via holes (21H) may be eliminated by laser irradiation or by desmear after laser irradiation.

(16) An electroless plating treatment is performed. Electroless plating films (not illustrated in the drawings) are respectively formed on the first insulating resin layers (21, 21) and in the via holes (21H, 21H).

(17) As illustrated in FIG. 7B, plating resists 40 of predetermined patterns are respectively formed on the electroless plating films on the copper foils 37.

(18) An electrolytic plating treatment is performed. As illustrated in FIG. 7C, the via holes (21H, 21H) are filled with plating and the via conductors (21D, 21D) are formed. Further, electrolytic plating films (39, 39) are respectively formed on portions of the electroless plating films (not illustrated in the drawings) on the first insulating resin layers (21, 21), the portions being exposed from the plating resists 40.

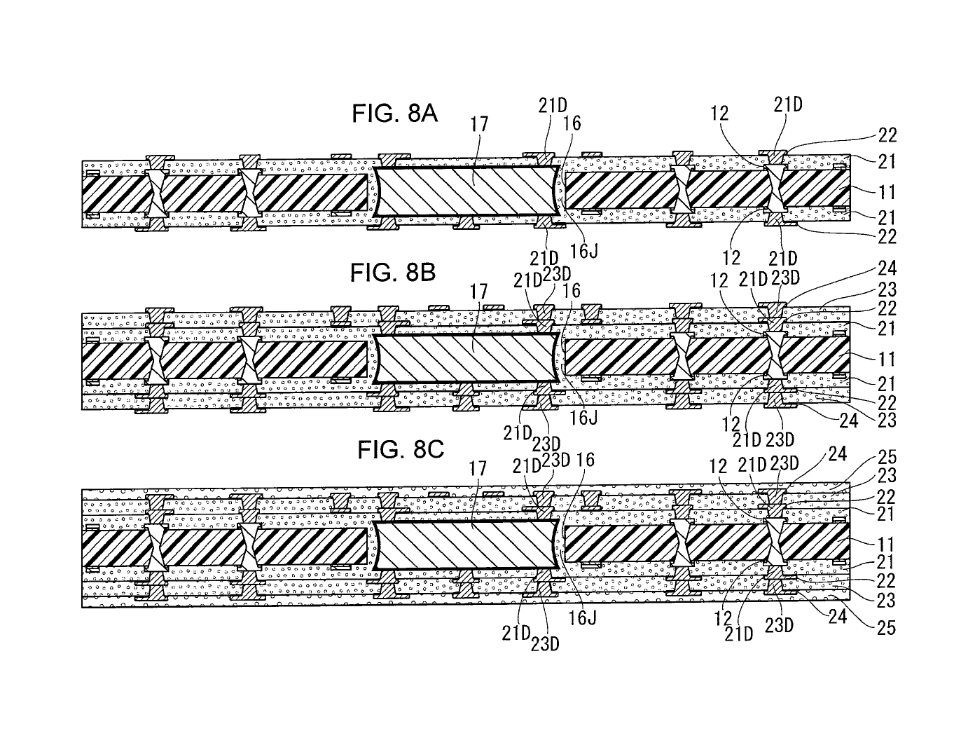

(19) The plating resists 40 are removed, and the electroless plating films (not illustrated in the drawings) and the copper foils 37, which are below the plating resists 40, are removed. As illustrated in FIG. 8A, the first conductor layers 22 are respectively formed on the first insulating resin layers 21 on the front and back sides of the core substrate 11 by the remaining electrolytic plating films 39, electroless plating films and copper foils 37. Then, a state is achieved in which, on each of the front and back sides of the core substrate 11, a portion of the first conductor layer 22 and the conductor circuit layer 12 are connected by the via conductors (21D), and the other portion of the first conductor layer 22 and the metal block 17 are connected by the via conductors (21D).

(20) By the same processing as described in the above (12)-(19), as illustrated in FIG. 8B, a state is achieved in which, on each of the front and back sides of the core substrate 11, the second insulating resin layer 23 and the second conductor layer 24 are formed on the first conductor layer 22, and a portion of the second conductor layer 24 and the first conductor layer 22 are connected by the via conductors (23D).

(21) As illustrated in FIG. 8C, the solder resist layers (25, 25) are respectively laminated on the second conductor layers 24 on the front and back sides of the core substrate 11.

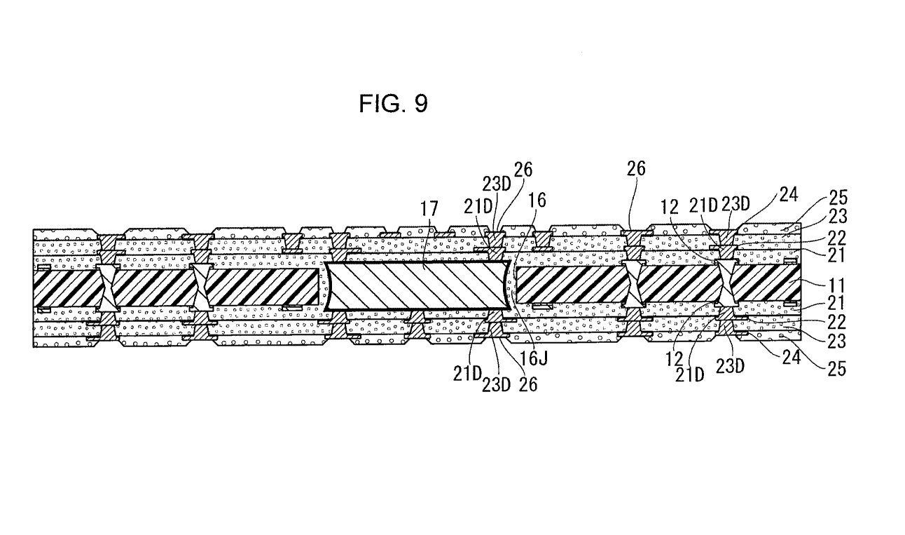

(22) As illustrated in FIG. 9, tapered pad holes are formed at predetermined places on the solder resist layers (25, 25) on the front and back sides of the core substrate 11, and portions of the second conductor layers 24 on the front and back sides of the core substrate 11 that are exposed from the pad holes become the pads 26.

(23) On each of the pads 26, a nickel layer, a palladium layer and a gold layer are laminated in this order and a metal film 41 illustrated in FIG. 3 is formed. As a result, the wiring board 10 with a built-in metal block is completed.

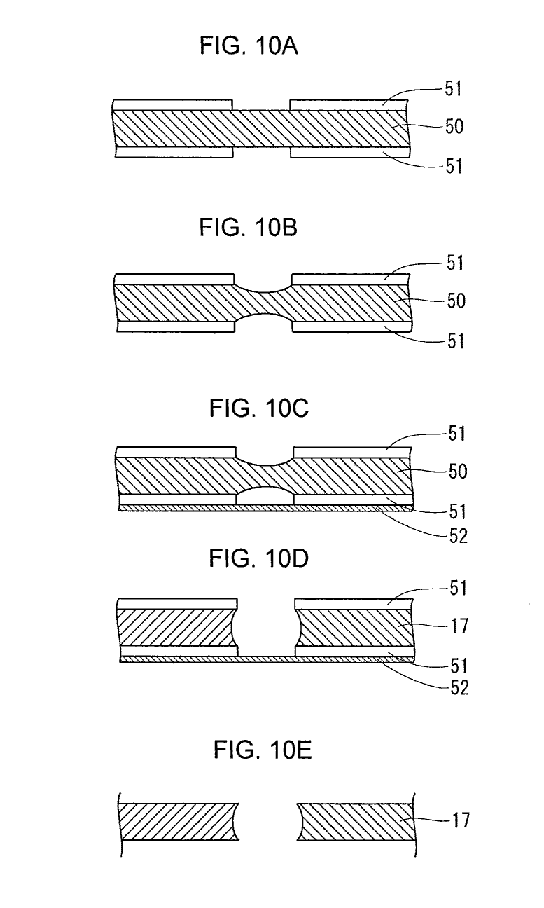

Next, a method for manufacturing the metal block 17 is described based on FIG. 10A-10E.

(1) A copper plate 50 is prepared.

(2) As illustrated in FIG. 10A, an etching resist 51 of a predetermined pattern is formed front and back surfaces of the copper plate 50.

(3) As illustrated in FIG. 10B, a portion of the copper plate 50 that is exposed from the etching resist 51 is half etched by an etching process.

(4) As illustrated in FIG. 10C, the copper plate 50 is affixed to a support member 52.

(5) As illustrated in FIG. 10D, the portion of the copper plate 50 that is exposed from the etching resist 51 is cut by an etching process. As a result, the metal block 17. Further, the etching process is performed until the side surfaces of the metal block 17 become the groove-shaped side surfaces (17A). That is, both the cutting of the copper plate 50 and the formation of the groove-shaped side surfaces (17A) are performed in one etching process. An “etching surface” in the present invention refers to a surface formed by etching.

(6) As illustrated in FIG. 10E, after the support member 52 is removed, the etching resist 51 is peeled off.

(7) the metal block 17 is dried.

(8) In a state of being accommodated in a container having an acid resistant mesh structure, the metal block 17 is immersed for predetermined period of time in an acid solution (for example, an acid of which main components are sulfuric acid and hydrogen peroxide) stored in a storage tank and thereafter is washed with water. As a result, the entire surface of the metal block 17 becomes a rough surface.

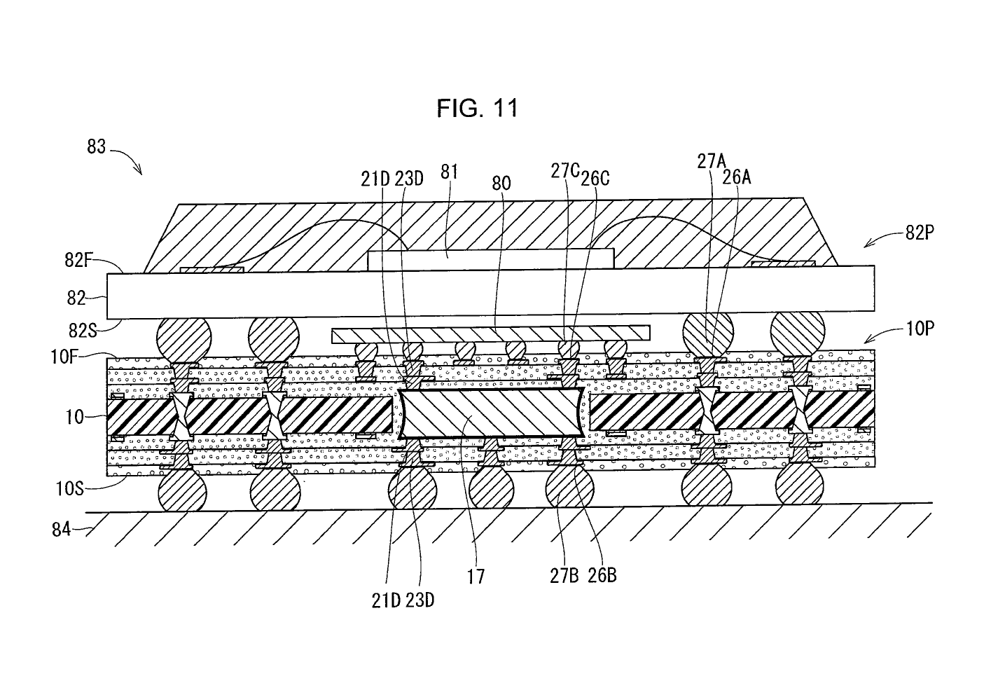

The description about the structure and the manufacturing method of the wiring board 10 with a built-in metal block of the present embodiment is as given above. Next, an operation effect of the wiring board 10 with a built-in metal block, together with an example of use of the wiring board 10 with a built-in metal block, is described. The wiring board 10 with a built-in metal block of the present embodiment is used, for example, as follows. That is, as illustrated in FIG. 11, large, medium and small solder bumps (27A, 27B, 27C) that respectively match the sizes of the above-described large, medium and small pads (26A, 26B, 26C) of the wiring board 10 with a built-in metal block are respectively formed on the large, medium and small pads (26A, 26B, 26C). Then, for example, a CPU 80 having on a lower surface a pad group that is similarly arranged as the small pad group on the F surface (10F) of the wiring board 10 with a built-in metal block is mounted on and soldered to the group of the small solder bumps (27C) of each product region (R2), and a first package substrate (10P) is formed. In this case, for example, two pads for grounding that the CPU 80 has are connected to the metal block 17 of the wiring board 10 with a built-in metal block via the via conductors (21D, 23D).

Next, a second package substrate (82P) that is obtained by mounting a memory 81 on an F surface (82F) of a wiring board 82 with a built-in metal block is arranged from an upper side of the CPU 80 on the first package substrate (10P). The large solder bumps (27A) of the wiring board 10 with a built-in metal block of the first package substrate (10P) are soldered to pads that are provided on an S surface (82S) of the wiring board 82 with a built-in metal block of the second package substrate (82P), and thereby a PoP 83 (Package on Package 83) is formed. Spacing between the wiring board 10 with a built-in metal block and the wiring board 82 with a built-in metal block in the PoP 83 is filled with a resin (not illustrated in the drawings).

Next, the PoP 83 is arranged on a motherboard 84. The medium solder bumps (27B) of the wiring board 10 with a built-in metal block in the PoP 83 are soldered to a group of pads of the motherboard 84. In this case, for example, a pad for grounding that the motherboard 84 has is soldered to a pad 26 of the wiring board 10 with a built-in metal block, the pad 26 being connected to the metal block 17. When the CPU 80 and the motherboard 84 have pads dedicated to heat dissipation, the pads dedicated to heat dissipation and the metal block 17 of the wiring board 10 with a built-in metal block may be connected to each other via the via conductors (21D, 23D).

When the CPU 80 generates heat, the heat is transmitted to the metal block 17 via the via conductors (21D, 23D) contained in the build-up layer 20 on the F surface (10F) side of the wiring board 10 with a built-in metal block, on which the CPU 80 is mounted, and is dissipated from the metal block 17 to the motherboard 84 via the via conductors (21D, 23D) contained in the build-up layer 20 on the S surface (10S) side of the wiring board 10 with a built-in metal block. Here, in the wiring board 10 with a built-in metal block of the present embodiment, the number of the via conductors (21D) that are connected to the metal block 17 is greater in the build-up layer 20 on the S surface (11S) side, to which the motherboard 84 as a heat dissipation destination is connected, than in the build-up layer 20 on the F surface (10F) side, on which the CPU 80 is mounted. Therefore, heat accumulation in the metal block 17 can be suppressed, and heat dissipation can be efficiently performed.

However, the wiring board 10 with a built-in metal block repeats thermal expansion and contraction due to use and non-use of the CPU 80. Then, due to the difference between the thermal expansion coefficient of the metal block 17 and the thermal expansion coefficient of the filling resin (16J), there is a concern that a gap may occur between the metal block 17 and the filling resin (16J) and efficiency of heat dissipation may decrease. However, in the wiring board 10 with a built-in metal block of the present embodiment, the side surfaces of the metal block 17 are groove-shaped side surfaces (17A) that are each curved so as to increase in depth toward the center. Therefore, a contact area between the metal block 17 and the filling resin (16J) can be increased as compared to a wiring board where the side surfaces of its metal block are flat surfaces, and thus the fixing strength can be increased. Further, since the contact area between the metal block 17 and the filling resin (16J) is increased, efficiency of heat dissipation from the metal block 17 to the wiring board 10 with a built-in metal block can be also be increased. Further, since the entire surface of the metal block 17 is a rough surface, fixation of the metal block 17, the first insulating resin layers (21, 21) and the filling resin (16J) in the cavity 16 can be further strengthened.

Further, in the present embodiment, the difference between the thermal expansion coefficient of the metal block 17 and the thermal expansion coefficient of the filling resin (16J) is smaller than the difference between the thermal expansion coefficient of the metal block 17 and the thermal expansion coefficient of the core substrate 11 in a direction parallel to the front and back surfaces of the core substrate 11. Therefore, a gap is unlikely to occur between the metal block 17 and the filling resin (16J).

Further, when processing from the copper plate 50 to the metal block 17 is performed by press processing or the like, the outer edge of the metal block 17 sags and there is a risk that a portion protruding from the F surface (11F) or the S surface (11S) may come into contact with the first conductor layer 22 and short circuiting may occur. In contrast, in the wiring board 10 with a built-in metal block of the present embodiment, the processing from the copper plate 50 to the metal block 17 is performed by an etching process. Therefore, the outer edge of the metal block 17 can be prevented from protruding from the F surface (11F) and the S surface (11S), and occurrence of short circuiting can be prevented.

### Second Embodiment

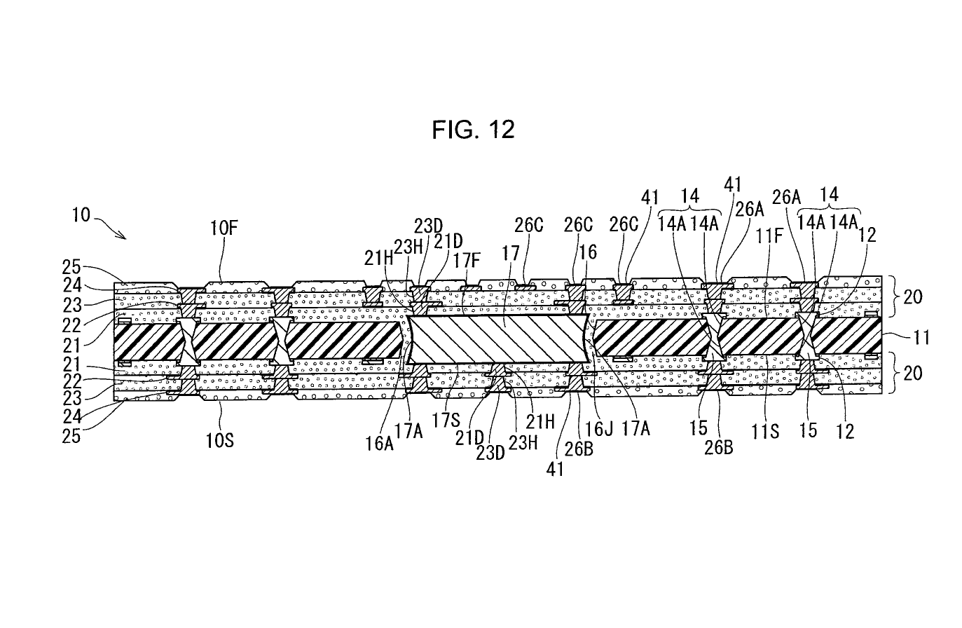

FIG. 12 illustrates a wiring board (10V) with a built-in metal block of the present embodiment. In the wiring board 10 with a built-in metal block of the first embodiment, the inner side surface of the cavity 16 is a flat surface (see FIG. 3). However, in the wiring board (10V) with a built-in metal block of the present embodiment, the inner side surface if the cavity 16 is a bulging side surface (16A) that bulges toward the groove-shaped side surface (17A). As a result, the filling resin (16J) can have a nearly uniform width, and it is likely that occurrence of a gap between the filling resin (16J) and the metal block 17, or the like, due to thermal expansion and contraction of the filling resin (16J), is regulated.

### Third Embodiment

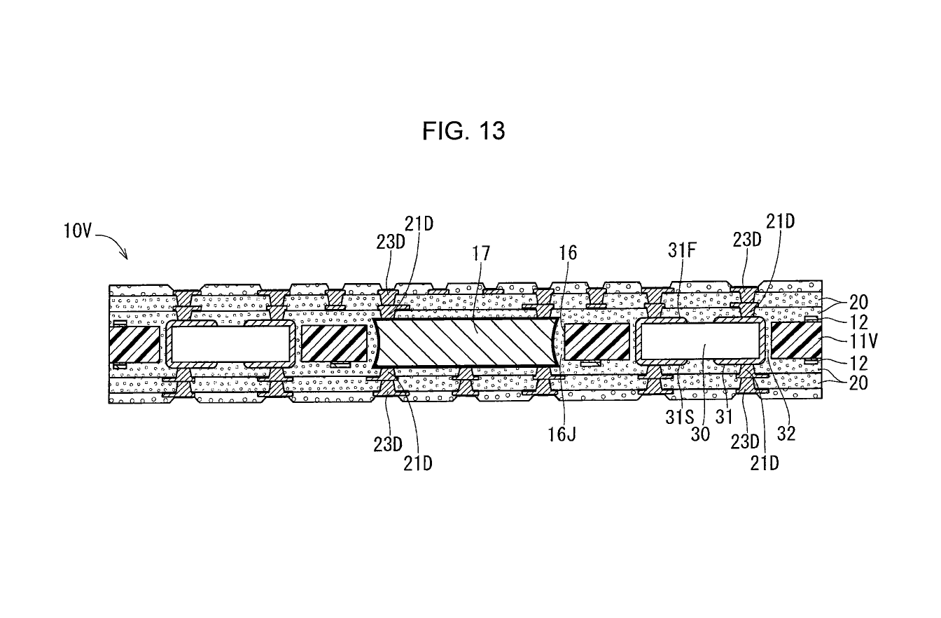

FIG. 13 illustrates a wiring board (10W) with a built-in metal block of the present embodiment. In the wiring board (10W) with a built-in metal block, cavities 32 that each accommodate, for example, a multilayer ceramic capacitor 30 are provided near the cavity 16 that accommodates the metal block 17. The multilayer ceramic capacitors 30 each have a structure in which, for example, two end portions of a ceramic prismatic body are covered by a pair of electrodes (31, 31). Further, similar to the metal block 17, the multilayer ceramic capacitors 30 each slightly protrude from an F surface (11F) and an S surface (11S) of a core substrate (11W). A first flat surface (31F) of each of the electrodes 31 of the multilayer ceramic capacitor 30 is flush with the outermost surface of the conductor circuit layer 12 on the F surface (11F) side of the core substrate (11W), and a second flat surface (31S) of each of the electrodes 31 of the multilayer ceramic capacitor 30 is flush with the outermost surface of the conductor circuit layer 12 on the S surface (11S) side of the core substrate (11W). Then, the via conductors (21D, 23D) contained in the build-up layers (20, 20) on both the front and back surfaces of the core substrate (11W) are connected to the electrodes 31 of the multilayer ceramic capacitors 30. Further, when the wiring board (10W) with a built-in metal block is manufactured, the metal block 17 and the multilayer ceramic capacitors 30 are respectively accommodated in the cavities (16, 32) in the same process.

### OTHER EMBODIMENTS

The present invention is not limited to the above-described embodiments. For example, the embodiments described below are also included in the technical scope of the present invention. Further, in addition to the embodiments described below, the present invention can also be embodied in various modified forms within the scope without departing from the spirit of the present invention.

(1) The via conductors (21D) of the first-third embodiments are in a state of being connected via the via conductors (23D) to the pads 26 that are exposed from the outermost surfaces of the wiring board (10, 10V, 10W) with a built-in metal block. However, for example, it is also possible to have a state in which conductors that are connected to the via conductors (21D) are not connected to portions that are exposed from the outermost surfaces of the wiring board (10, 10V, 10W) with a built-in metal block, such as a state in which the via conductors (23D) are not connected or the pads 26 are not provided.

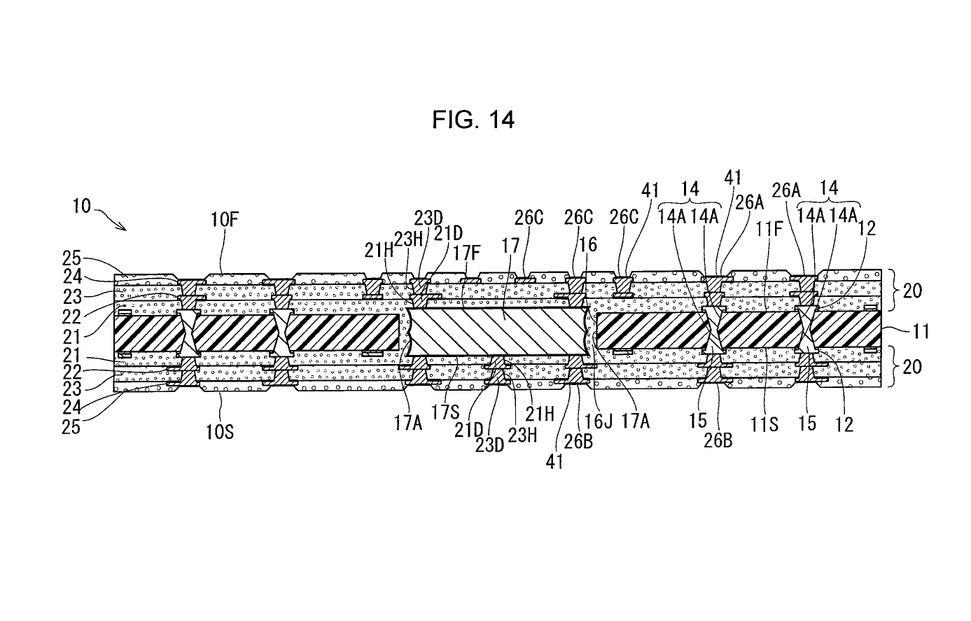

(2) Only one groove is formed on each of the groove-shaped side surfaces (17A) of the metal block 17 in the first-third embodiment. However, as illustrated in FIG. 14, it is also possible that two grooves are formed in each of the side surfaces.

(3) The surfaces of the metal block 17 in the first-third embodiments are roughened after the copper plate 50 is cut. However, the surfaces may also be roughened before the cutting (specifically, before the etching resist 51 is formed). In this case, all the side surfaces or portions of the side surfaces of the metal block 17 are in a state of being not roughened.

(4) The surfaces of the metal blocks of the first-third embodiments are roughened using an acid. However, for example, it is also possible that the roughening of the surfaces is performed by spraying particles or by pressing the surfaces against an uneven surface.

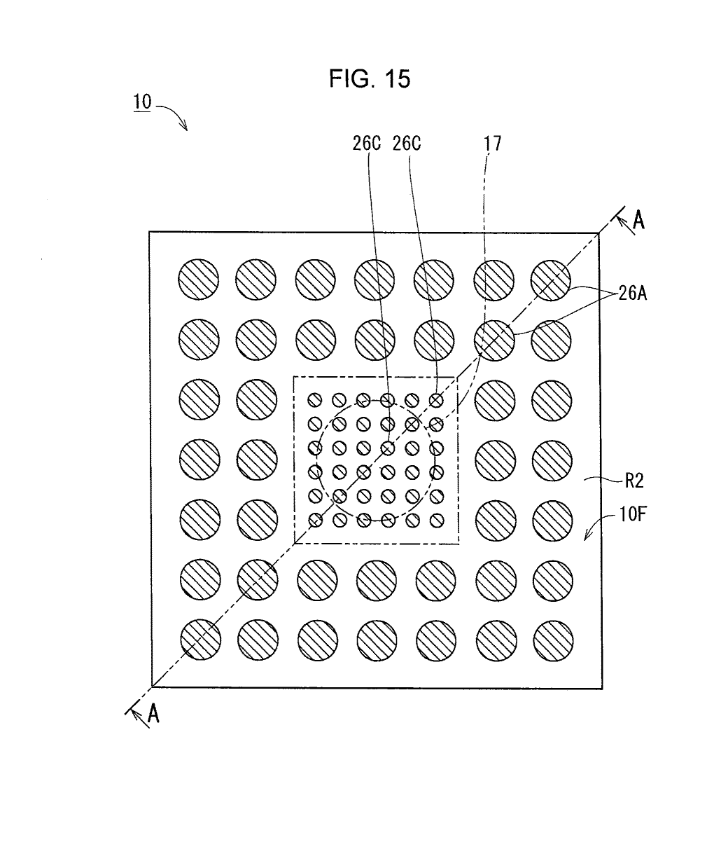

(5) The planar shape of the metal block 17 in the first-third embodiments is rectangular. However, the planar shape of the metal block 17 may also be other polygonal shapes, and may also be circular as illustrated in FIG. 15, and may also be elliptical or oval.

(6) The metal block 17 in the first-third embodiments is made of copper. However, the present invention is not limited to this. For example, the metal block 17 may also be made of a mixture of copper and molybdenum or tungsten, or made of aluminum or the like.

(7) In the above-described embodiments, the number of the via conductors (21D) that are connected to the metal block 17 is larger on the S surface (17S) side, where the motherboard 84 as a heat dissipation destination is connected, than on the F surface (17F) side, where the CPU 80 is mounted. However, it is also possible that the number of the via conductors (21D) is the same on the two sides, or is greater on the S surface (17S) side. In the case where the number of the via conductors (21D) on the S surface (17S) side is larger, when the metal block 17 is arranged in a region directly below the CPU 80, heat generated by the CPU 80 can be efficiently dissipated.

In a conventional wiring board with a built-in metal block, it is likely that fixing strength of its metal block in the substrate is low.

A wiring board with a built-in metal block according to an embodiment of the present invention allows fixing strength of the metal block in a substrate to be higher as compared to a conventional wiring board with a built-in metal block, and another embodiment of the present invention is a method for manufacturing such a wiring board with a built-in metal block.

A wiring board with a built-in metal block according to one aspect to the present invention includes: a substrate; a cavity that penetrates the substrate; a metal block that is accommodated in the cavity and has a first primary surface (which is a front surface), a second primary surface (which is a back surface), and a side surface that connects between an outer edge of the first primary surface and an outer edge of the second primary surface; a filling resin that is filled in a gap between an inner side surface of the cavity and the side surface of the metal block; and build-up layers that are respectively laminated on front and back sides of the substrate, and respectively include insulating resin layers that cover the cavity and the front and back surfaces of the metal block. The side surface of the metal block is recessed in a groove shape.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring board with a built-in metal block, comprising:
a substrate having a cavity such that the cavity is penetrating through the substrate;
a metal block accommodated in the cavity of the substrate and formed such that the metal block has a first surface, a second surface on an opposite side of the first surface, and a side surface connecting an outer edge of the first surface and an outer edge of the second surface;
a filling resin filling a gap formed between an inner side surface of the substrate in the cavity and the side surface of the metal block;
a first build-up layer laminated on a first surface of the substrate and comprising an insulating resin layer such that the first build-up layer is covering the cavity and the first surface of the metal block in the cavity; and
a second build-up layer laminated on a second surface of the substrate and comprising an insulating resin layer such that the second build-up layer is covering the cavity and the second surface of the metal block in the cavity,
wherein the side surface of the metal block is recessed such that the side surface of the metal block is forming a groove shape.

2. A wiring board with a built-in metal block according to claim 1, wherein the side surface of the metal block is curving such that the groove shape of the side surface becomes deeper toward a center between the first surface and the second surface.

3. A wiring board with a built-in metal block according to claim 1, wherein the side surface of the metal block is formed such that the side surface and the first surface is forming a corner having an angle in a range of 30 degrees or more to less than 90 degrees and that the side surface and the second surface is forming a corner having an angle in a range of 30 degrees or more to less than 90 degrees.

4. A wiring board with a built-in metal block according to claim 1, wherein the side surface of the metal block is formed such that the side surface has a maximum depth in a range of 10% to 20% of a distance between the first surface and the second surface.

5. A wiring board with a built-in metal block according to claim 1, wherein the side surface of the metal block is formed such that the side surface has a maximum depth in a range of 10 μm to 20 μm.

6. A wiring board with a built-in metal block according to claim 1, wherein the side surface of the metal block is recessed such that the side surface of the metal block is forming the groove shape continuously extending around the metal block in a circumferential direction.

7. A wiring board with a built-in metal block according to claim 6, wherein the side surface of the metal block comprises an etching surface.

8. A wiring board with a built-in metal block according to claim 1, wherein the substrate is formed such that the inner side surface of the substrate in the cavity is a bulging side surface projecting toward the side surface of the metal block.

9. A wiring board with a built-in metal block according to claim 1, wherein the substrate, the filler resin and the metal block are formed such that a difference between a thermal expansion coefficient of the metal block and a thermal expansion coefficient of the filling resin is smaller than a difference between the thermal expansion coefficient of the metal block and a thermal expansion coefficient of the substrate in a direction parallel to the first and second surfaces of the substrate.

10. A wiring board with a built-in metal block according to claim 2, wherein the side surface of the metal block is formed such that the side surface and the first surface is forming a corner having an angle in a range of 30 degrees or more to less than 90 degrees and that the side surface and the second surface is forming a corner having an angle in a range of 30 degrees or more to less than 90 degrees.

11. A wiring board with a built-in metal block according to claim 2, wherein the side surface of the metal block is formed such that the side surface has a maximum depth in a range of 10% to 20% of a distance between the first surface and the second surface.

12. A method for manufacturing a wiring board with a built-in metal block, further comprising:
forming a cavity in a substrate such that the cavity penetrates through the substrate;
accommodating a metal block in the cavity of the substrate such that the metal block has a first surface on a first surface side of the substrate, a second surface on a second surface side of the substrate on an opposite side of the first surface, and a side surface connecting an outer edge of the first surface and an outer edge of the second surface;
filling a filling resin into a gap formed between an inner side surface of the substrate in the cavity and the side surface of the metal block;
forming a first build-up layer laminated on the first surface side of the substrate and comprising an insulating resin layer such that the first build-up layer covers the cavity and the first surface of the metal block in the cavity; and
forming a second build-up layer laminated on a second side of the substrate and comprising an insulating resin layer such that the second build-up layer covers the cavity and the second surface of the metal block in the cavity,
wherein the side surface of the metal block is recessed such that the side surface of the metal block is forming a groove shape.

13. A method for manufacturing a wiring board with a built-in metal block according to claim 12, further comprising:
forming the metal block such that the side surface of the metal block is curving and that the groove shape of the side surface becomes deeper toward a center between the first surface and the second surface.

14. A method for manufacturing a wiring board with a built-in metal block according to claim 12, further comprising:
forming the metal block such that the side surface and the first surface forms a corner having an angle in a range of 30 degrees or more to less than 90 degrees and that the side surface and the second surface forms a corner having an angle in a range of 30 degrees or more to less than 90 degrees.

15. A method for manufacturing a wiring board with a built-in metal block according to claim 12, further comprising:
forming the metal block such that the side surface has a maximum depth in a range of 10% to 20% of a distance between the first surface and the second surface.

16. A method for manufacturing a wiring board with a built-in metal block according to claim 12, further comprising:
forming the metal block such that the side surface has a maximum depth in a range of 10 μm to 20 μm.

17. A method for manufacturing a wiring board with a built-in metal block according to claim 12, further comprising:
forming the metal block such that the side surface of the metal block is forming the groove shape continuously extending around the metal block in a circumferential direction.

18. A method for manufacturing a wiring board with a built-in metal block according to claim 12, further comprising:
preparing a metal plate having an etching resist having a pattern; and
etching the metal plate such that the metal plate is cut at part exposed by the pattern of the etching resist and that the metal block is formed.

19. A method for manufacturing a wiring board with a built-in metal block according to claim 12, further comprising:
preparing a metal plate having an etching resist having a pattern;
etching the metal plate such that the metal plate is partially etched at part exposed by the pattern of the etching resist;
attaching on a support the metal plate partially etched at the part exposed by the pattern of the etching resist; and
etching the metal plate attached on the support such that the metal plate is cut at the part exposed by the pattern of the etching resist and that the metal block is formed.

20. A method for manufacturing a wiring board with a built-in metal block according to claim 12, wherein the substrate, the filler resin and the metal block are formed such that a difference between a thermal expansion coefficient of the metal block and a thermal expansion coefficient of the filling resin is smaller than a difference between the thermal expansion coefficient of the metal block and a thermal expansion coefficient of the substrate in a direction parallel to first and second surfaces of the substrate.
